(19) United States
(12) Patent Application Publication
(10) Pub. No.: US 2005/0111583 A1
(43) Pub. Date: May 26, 2005

(54) Delay device, power supply device, and program product for delaying signal

(75) Inventor: Yoshihiro Komatsuzaki, Ibaraki (JP)

Correspondence Address: REED SMITH, LLP;ATTN: PATENT RECORDS DEPARTMENT, 599 LEXINGTON AVENUE, 29TH FLOOR, NEW YORK, NY, 10022-7650, US

(73) Assignee: DENSEI-LAMBDA K.K.

(21) Appl. No.: 10/874,074

(22) Filed: Jun. 22, 2004

(30) Foreign Application Priority Data
Nov. 26, 2003 (JP) 2003-395232

(51) Int. Cl. H03K 9/00

(52) U.S. Cl. 375/316

(57) ABSTRACT

A delay device with high resolution is provided without increasing circuit size. In the delay device which is inputted a signal with periodicity and outputs the signal after a delay by a prescribed time, there are provided a sampling circuit for sampling the signals at intervals of a prescribed time period, a storage circuit for storing data sampled by the sampling circuit in a past certain amount of time, and an estimation circuit for estimating the value of the signal at a time that is a prescribed time period before a certain time point and between the samplings based on the data stored in the storage circuit.

The disclosure of Japanese Patent Application No.2003-395232 filed Nov. 26, 2003 including specification, drawings and claims is incorporated herein by reference in its entirety.

### BACKGROUND OF THE INVENTION

1. Field of the Invention

The present invention relates to a delay device, a power supply device, and a program product for delaying signals.

2. Description of the Related Art

For obtaining a value of a waveform such as of electric voltage or electric current at a time that is an arbitrary time T₀ before, what has to be done is only to delay the waveform such as of the electric voltage or electric current by the time T₀ with a delay element (dead-time element) as shown in FIG. 10A. Incidentally, here, S is a Laplace operator.

In addition, for realizing the delay element that operates for a discrete time, the delay element as shown in FIG. 10B is used. Here, Z is an operator for z-transform, N indicates an order of signals, and they are set to satisfy T₀=Tₛ×N.

For realizing the delay element as shown in FIG. 10B, there is a method as shown for example in claims and abstract of Japanese Patent Application Laid-Open No. Hei 05-225319, in which a plurality of shift registers are provided and time-series data are cyclically inputted into the plurality of shift registers to thereby delay the data.

Also, there is another method as shown in FIG. 11 in which data obtained in a sampling by an AID (Analog to Digital) converter 101 are stored in a RAM (Random Access Memory) 104 to be outputted via an I/F (Interface) 105 after an elapse of the prescribed time T₀.

This example is composed of the A/D converter 101, a CPU (Central Processing Unit) 102, a ROM (Read Only Memory) 103, the RAM 104, and the I/F 105.

The waveform inputted into the AID converter 101 is sampled at intervals of the prescribed time period Tₛ to thereby be stored in the RAM 104 sequentially via the CPU 102. The data stored in the RAM 104 are sequentially read out by the CPU 102 when the prescribed time T₀ has passed after the sampling to thereby be outputted via the I/F 105.

According to the above-described operation, it is possible to delay the output of the input waveform by the time T₀.

However, in the method shown in the above-stated patent document, for improving resolution of the data to be outputted, there is a problem of increasing circuit size since many shift resisters are required therein.

Meanwhile, in the method shown in FIG. 11, for improving resolution, there is a problem of increasing circuit size, since the sampling period Tₛ is needed to be shorten for the improvement, which yet requires the RAM 104 with larger memory capacity.

The present invention is made based on the above-mentioned considerations, and an object of the present invention is to provide a delay device with high resolution without increasing circuit size, a power supply device employing such a delay device, and a program product for delaying signals for realizing such a delay device.

### SUMMARY OF THE INVENTION

To attain the above-mentioned object, according to the present invention, a delay device which is inputted a signal with periodicity and outputs the signal after a delay by a prescribed time T₀ includes a sampling circuit for sampling the signals with periodicity at intervals of a prescribed time period Tₛ, a storage circuit for storing data sampled by the sampling circuit in a past certain amount of time, and an estimation circuit for estimating a value of the signal at a time that is the prescribed time T₀ before a certain time point and between the samplings based on the data stored in the storage circuit.

This allows offering the delay device with high resolution without increasing circuit size.

In another invention, in addition to the above-described invention, the estimation circuit estimates the value of the signal at the time that is the prescribed time T₀ before using M (M>1) data stored in the storage circuit and existing in the vicinity of the datum to be estimated by interpolating the data into an (M−1) polynominal. This allows correct estimation even with a small number of data.

In still another invention, in addition to the above-described inventions, the estimation circuit estimates the value of the signal at the time that is the prescribed time T₀ before using four data stored in the storage circuit and existing in the vicinity of the datum to be estimated by interpolating the data into a cubic polynominal. This allows obtaining further approximate output signal to an ideal waveform.

In still another invention, in addition to the above-described inventions, the delay device further includes a measurement circuit for measuring a time period of the signal, and a reset means for resetting a value of a parameter used by the estimation circuit for estimating the value of the signal in response to the measurement result of the measurement circuit. This allows correct estimation even in the case of the signal fluctuating.

In still another invention, in addition to the above-described inventions, the sampling circuit samples at shorter intervals than those for storing in the storage circuit and there is further included a filtering circuit for filtering the data sampled by the sampling circuit. This allows preventing occurance of aliasing.

Further, in the present invention, a power supply device having the delay device which is inputted a detection signal of voltage or current of a commercial power source and outputs the same after the delay by the prescribed period of time T₀ being a time period of the voltage or current of the commercial power source or its integral multiple icludes a sampling circuit for sampling the detection signals of the voltage or current of the commercial power source at intervals Ts being shorter than the prescribed period of time T₀ that is a time period of the voltage or current of the commercial power source or its integral multiple, a storage circuit for storing the data sampled by the sampling circuit in a past certain amount of time, an estimation circuit for estimating a value of a detection signal at one point being the prescribed time T₀ before the certain time point and between the samplings based on the data stored in the storage circuit, and a control circuit for controlling an internal circuit of the power supply device based on the value obtained by the estimation circuit.

Therefore, in the power supply device such as a switching power supply and an uninterruptible power supply, it is possible to realize the delay element of the resolution enough for control with a small memory capacity.

Furthermore, in the present invention, a computer-readable program product for delaying signals, which makes a computer execute a processing of inputting the signal with periodicity and outputting the same after the delay by the prescribed time T₀, makes the computer to function as a sampling means for sampling the signals with periodicity at intervals of the prescribed time period Tₛ, a storage means for storing the data sampled by the sampling means in a past certain amount of time, an estimate means for estimating the value of the signal the prescribed time T₀ before based on the data stored in the storage means, and output means for outputting the value obtained by the estimate means.

Therefore, with this program product being installed, it is possible to provide the delay device with high resolution without increasing circuit size.

### BRIEF DESCRIPTION OF THE DRAWINGS

FIG. 1 is a circuit diagram showing a configuration example according to an embodiment of the present invention;

FIG. 2 is a diagram for explaining an operation of the embodiment shown in FIG. 1;

FIG. 3 is a flowchart for explaining an operation of the embodiment shown in FIG. 1;

FIG. 4 is a flowchart for explaining an example of a specific processing in Step S15 to S19;

FIG. 5 is a configuration example of a circuit for examining validity of a delay circuit shown in FIG. 1;

FIG. 6A is a diagram showing an input signal of the circuit shown in FIG. 5;

FIG. 6B is a diagram showing a disturbance inputted into the circuit shown in FIG. 5;

FIG. 7A is a diagram showing an ideal output signal of the circuit shown in FIG. 5;

FIG. 7B is a diagram showing an actual output signal when M=1 in the circuit shown in FIG. 5;

FIG. 8A is a diagram showing the actual output signal when M=2 in the circuit shown in FIG. 5;

FIG. 8B is a diagram showing the actual output signal when M=4 in the circuit shown in FIG. 5;

FIG. 9 is a diagram showing the actual output signal when M=6 in the circuit shown in FIG. 5;

FIG. 10A is a diagram showing an example of a conventional delay circuit in continuous-time;

FIG. 10B is a diagram showing an example of a conventional delay circuit in discrete time; and

FIG. 11 is a diagram showing a specific configuration example of the delay circuit in FIG. 10B.

### DETAILED DESCRIPTION OF THE PREFERRED EMBODIMENTS

Hereinafter, an embodiment of the present invention will be described based on the accompanying drawings.

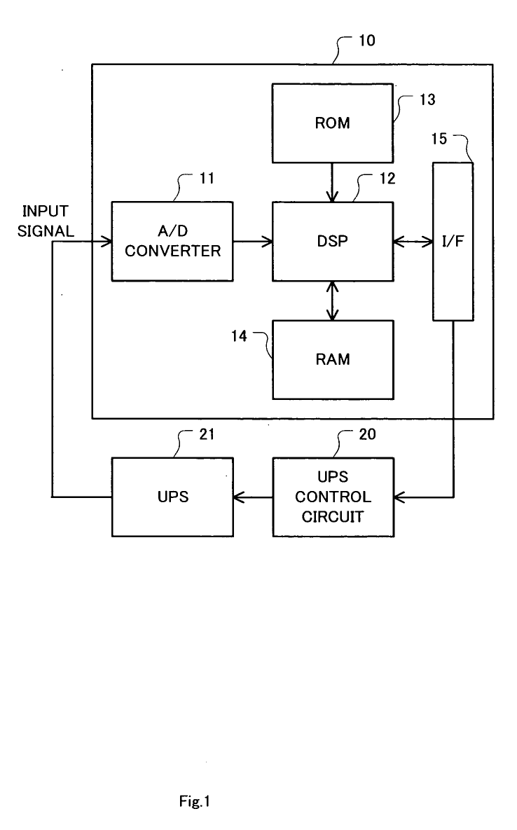

FIG. 1 is a circuit diagram showing a configuration example of the embodiment of the present invention. As shown in the drawing, a power supply device according to the embodiment of the present invention is configured by a delay circuit 10, a UPS (Uninterruptible Power Supply System), a control circuit 20, and a UPS 21.

The delay circuit 10 is configured by an AID converter 11, a DSP (Digital Signal Processor) 12, a ROM 13, a RAM 14, and an I/F 15, and inputs for example output voltages of the UPS 21 controlled by the UPS control circuit 20 as an input signal and outputs them after a delay by a prescribed time T₀.

Here, the A/D converter 11, which is a sampling circuit, samples an output voltage or an output current of the UPS 21 at intervals of the prescribed time period Tₛ and outputs after converting the same into digital data. The DSP 12, as an estimation circuit, a measurement circuit, a reset means, and a filtering circuit, outputs the digital data outputted from the A/D converter 11 after conducting a prescribed calculation processing.

The ROM 13 stores a program to be executed by the DSP 12. As a storage circuit, the RAM 14 temporarily stores data in the course of the processing, when the DSP 12 executes a prescribed processing. The I/F 15, which is an output circuit, supplies the data outputted from the DSP 12 to the UPS control circuit 20.

The UPS 21 is a so-called uninterruptible power supply device and provided with an internal battery, so that it outputs electric power from the battery after converting it into ac power in case of electric power outage. The UPS control circuit 20 is a control circuit for controlling the UPS 21 and executes a selective block control or the like for selectively blocking the UPS for example when a plurality of UPSs are operated in parallel and any of the UPSs is down, in response to the signals outputted from the delay circuit 10.

Note that the delay circuit 10 and the UPS control circuit 20 are provided outside the UPS 21 here, however, the delay circuit 10 and the UPS control circuit 20 may be provided inside the UPS 21.

Next, the operation of the above-described embodiment will be outlined.

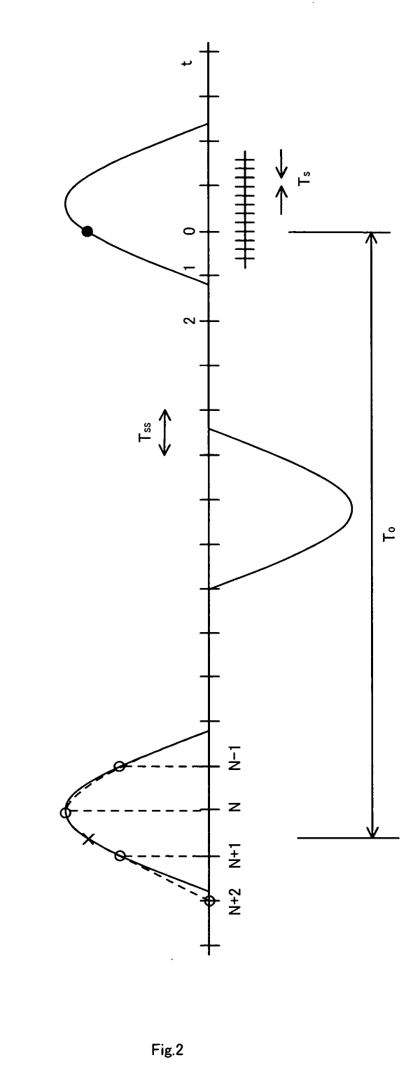

FIG. 2 is a diagram showing a relation of a sampling time period Tₛ, a thinned-out sampling time period Tₛₛ, and a delay time T₀. In the drawing, a periodically-repeated waveform shows, for example, an output current of the UPS 21.

The sampling time period Tₛ indicates a time period in which the A/D converter 11 samples an input signal. The thinned-out sampling time period Tₛₛ indicates a substantial sampling time period which is after the data sampled by the A/D converter 11 being thinned out at a constant rate by the DSP 12.

The delay time T₀ indicates a time intended to delay and, in this embodiment, the time from t=0 to the position denoted by the numeral symbol 42.

If the thinned-out rate is m, the following relation will be established between the thinned-out sampling time period Tₛₛand the sampling time period Tₛ. Note that m=5 in the example in FIG. 2.
Tₛₛ=m·Ts (equation 1)

Where a primary number of division N is defined as follows. Note that a floor [ ] is a floor function which gives an integral number of the number in parentheses by rounding down fractions below decimal point.

$$N = floor [ \frac{{T}_{0}}{{T}_{ss}} ] \qquad ( equation 2 )$$

When calculating the signal value at a time that is T₀ before (the value denoted by the numeral symbol 42 in FIG. 2) based on the signal value in the case of t=0 (the value denoted by the numeral symbol 45 in FIG. 2), there is no data for the numeral symbol 42 since the numeral symbol is positioned between the sampling points so that, in this embodiment, the data is estimated using M data in the vicinity of the primary number of division N with an (M−1) polynominal. That is, y (t) represents an input signal value at each time, and when M=4, y(t−T₀) is expressed by the following equation.
y(t−T₀)≅a₁y[N−1]+a₂y[N]+a₃y[N+1]+a₄y[N+2] (equation 3)

Where, coefficients a₁ to a₄ contained in the equation 3 are calculated by the following equation,

$$[ \begin{matrix}{a}_{1} \\ {a}_{2} \\ {a}_{3} \\ ⋮ \\ {a}_{M}\end{matrix} ] = {[ \begin{matrix}1 & 1 & 1 & ⋯ & 1 \\ {D}_{1} & {D}_{2} & {D}_{3} & ⋯ & {D}_{M} \\ {D}_{1}^{2} & {D}_{2}^{2} & {D}_{3}^{2} & ⋯ & {D}_{M}^{2} \\ ⋮ & ⋮ & ⋮ & ⋰ & ⋮ \\ {D}_{1}^{M - 1} & {D}_{2}^{M - 1} & {D}_{3}^{M - 1} & ⋯ & {D}_{M}^{M - 1}\end{matrix} ]}^{- 1} = [ \begin{matrix}1 \\ 0 \\ 0 \\ ⋮ \\ 0\end{matrix} ] \qquad ( Equation 4 )$$

Provided that Dᵢ is calculated by the following equation.

$${D}_{1} := \frac{{N}_{i} {T}_{ss}}{{T}_{0}} - 1 \qquad ( equation 5 )$$

Specifically, if T₀ is a desired time to delay, Ts is a sampling time, and N₁=20, N₂=21, N₃=22, and N₄=23, according to the equation 5, the coefficients a₁ to a₄ become a₁=−0.0623, a₂=0.5564, a₃=0.5685, a₄=−0.0627 respectively, assuming that Ni (i=1, 2, 3, 4) indicates respective current values at time points (N−1), N, (N+1), (N+2) in FIG. 2, and the sampling timing is between N and N+1.

Subsequently, the description will be provided for the operation of the embodiment shown in FIG. 1.

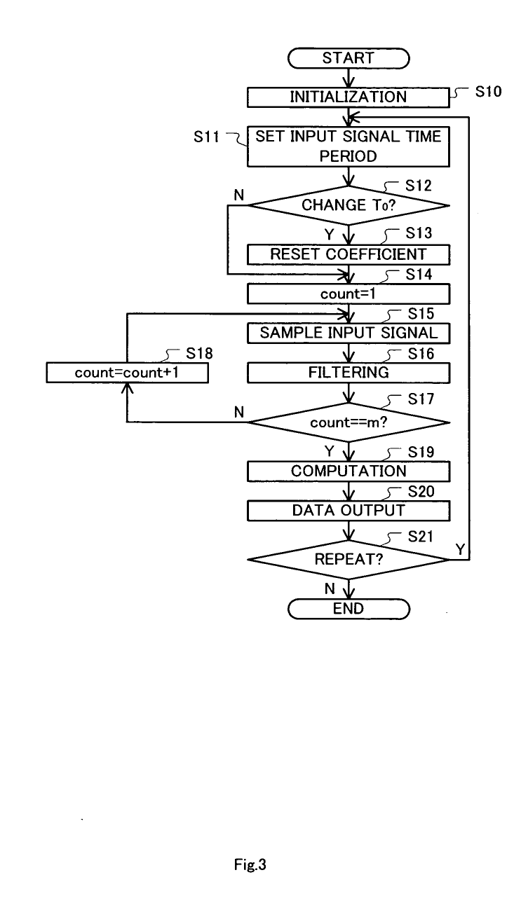

FIG. 3 is a flowchart for explaining an example processing executed in the embodiment shown in FIG. 1. In this flowchart, the following steps are included.

Step S10: the DSP 12 initializes various types of parameters.

Step S11: the DSP 12 measures a time period of an inputted signal.

Specifically, the time period is measured by measuring a time between zero-cross points of the inputted signals.

Step S12: the DSP 12 determines whether or not the delay time T₀ is changed. That is, when the time periods of the inputted signals fluctuate, the delay time T₀ is required to be changed, thereby the DSP 12 goes to Step S13 if the delay time T₀ is changed and the DSP 12 goes to Step S14 if the delay time T₀ is unchanged.

Step S13: the DSP 12 executes a processing for resetting the values of the coefficients a₁ to a₄ as parameters. Specifically, the values of the coefficients a₁ to a₄ as parameters are reset based on the equations 4 and 5.

Step S14: the DSP 12 assigns “1” as an initial value to a parameter count which counts the number of processings.

Step S15: the DSP 12 obtains sampled data outputted from the A/D converter 11.

Step S16: the DSP 12 filters the data obtained in Step S15. Specifically, the DSP 12 executes a processing for example of applying a 2nd order low-pass filter to the data obtained in Step S15. For information, this processing is carried out for preventing aliasing from occurring.

Step S17: the DSP 12 determines whether or not the value of the parameter count equals to the thinned-out rate m, and if equals, goes to Step S19, and if not, goes to Step S18.

Sep S18: the DSP 12 gives an increment to the value of the parameter count by one and returns to Step S15 to thereby repeat the same processes.

Step S19: the DSP 12 executes a computation for obtaining the input signal at the time that is T₀ before. That is, to obtain the product of y (t−T₀) using the equation 3. For reference, this processing will be detailed later.

Step S20: the DSP 12 outputs via the I/F 15 an estimated value of the input signal at the time that is T₀ before obtained in Step S19.

Step S21: the DSP 12 determines whether or not to repeat the processing, and if yes, returns to Step S11 to repeat the same processing, and if not, ends the processing.

Through the above processing, it is possible to obtain and output the estimate value of the input signal T₀ before.

Subsequently, the caluculation processings shown in Step S15 to S20 will be detailed.

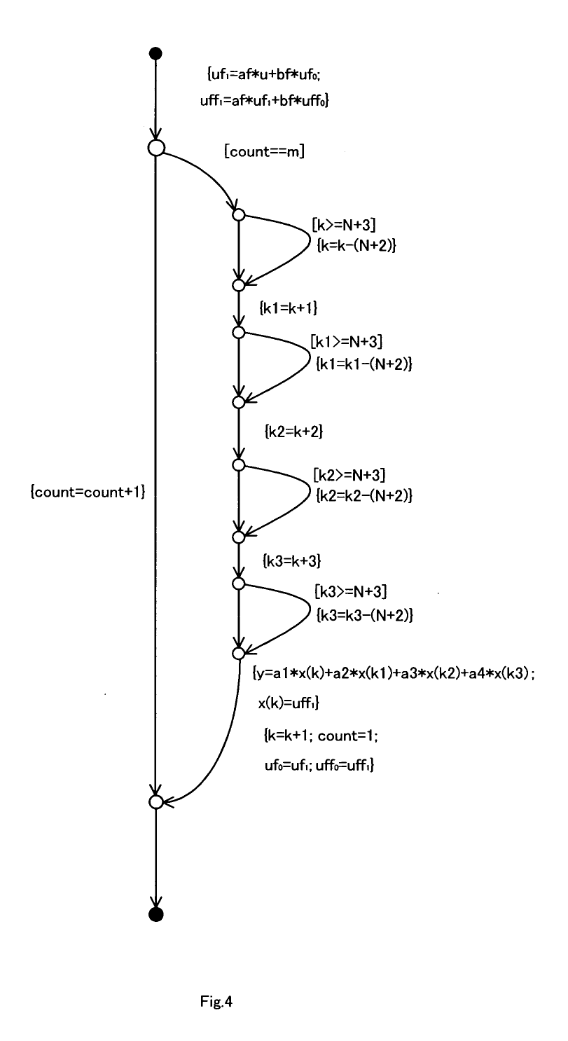

FIG. 4 is a diagram for explaining the details of the processings in Step S15 to S29. In this drawing, a black circle indicates start or end of the processing, a white circle indicates a branch point or a confluence of the processing, and an arrow indicates a processing flow. Inside [ ] is a criterion for branching, and inside { } is an assignment processing to be executed.

After starting the processing shown in the drawing, first, a filtering is performed. Here, u indicates an input signal, uf₀ and uf₁ are variables to store mid-flow status of the filtering, uff₀ and uff₁ are variables to store data completed the filterling, and af and bf are filter coefficients. An equation x (n) (N=1, 2, . . . , (N+3)) is an array to store filtered data. The k, k1 to k3 are variables to assign an address to an array. Incidentally, a storage area for these variables is provided in a not-shown register of the DSP 12 or in the RAM 14.

As shown in FIG. 4, after the start of the processing, first, the filtering is executed. In the filtering, firstly, af*u+bf*uf₀ (“*” indicates multiplication) is calculated and the product is stored in the uf₁. Secondly, af*uf₁+bf*uff₀ is calculated and the product is stored in the uff₁. Here, for the uf₀ and uff₀, their most vicinal previous values of uf₁ and uff₁ are substituted. Incidentally, this filtering is executed for the purpose of preventing the occurrence of the aliasing.

Subsequently, the value of the variable count is compared with the thinned-out magnification m, and if they are the same, then the flow branches to the right side in FIG. 4, and if not, the flow branches to immediate below, and the value of the variable count is incrementally changed by one.

When branched to the right side, the value of k is determined whether or not it equals to (N+3) or more, and if it does, the flow branches to the right side, and the value of the k is updated to (k−(N+2)). If not, the, flow branches to immediate below to thereby go to the next processing without doing anything.

Subsequently, the variable k1 is updated to the value of (k+1), and the k1 is determined whether or not it equals to (N+3) or more, if it does, the flow branches to the right side to thereby update the k1 to the value of (k1−(N+2)). If not, the flow branches to immediate below to thereby go to the next processing without doing anything.

Subsequently, a variable k2 is updated to the value of (k+2). Then, the k2 is determined whether or not it equals to (N+3) or more, and if it does, the flow branches to the right side to thereby update the k2 to the value of (k2−(N+2)). If not, the flow branches to immediate below to thereby go to the next processing without doing anything.

Subsequently, a variable k3 is updated to the value of (k+3). Then, the k3 is determined whether or not it equals to (N+3) or more, and if it does, the flow branches to the right side to thereby update the k3 to the value of (k3−(N+2)). If not, the flow branches to immediate below to thereby go to the next processing without doing anything.

Subsequently, the estimate value of the input sinal that is T₀ before is calculated by a1*x(k)+a2*x(k1)+a3*x(k2)+a4*x(k3) to thereby substitute the product for the variable y. Also, the value of the uff₁ is substituted for an array x (k).

Subsequently, the values of the variable k and the variable count are incrementally changed by one respectively, and the uf₀ is updated to the value of the uf₁ and the uff₀ is updated to the value of the uff₁.

The processings of Step S15 to S20 shown in FIG. 3 can be realized by the above-described processings.

Subsequently, validity of the embodiment of the present invention will be described.

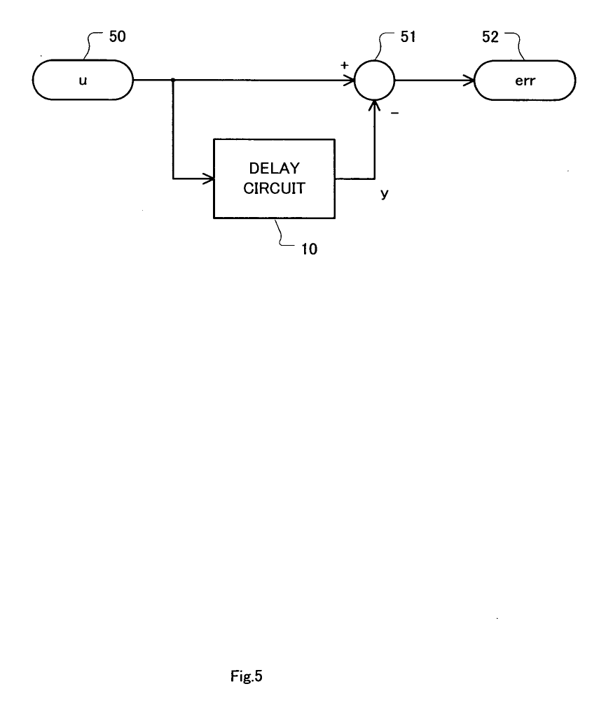

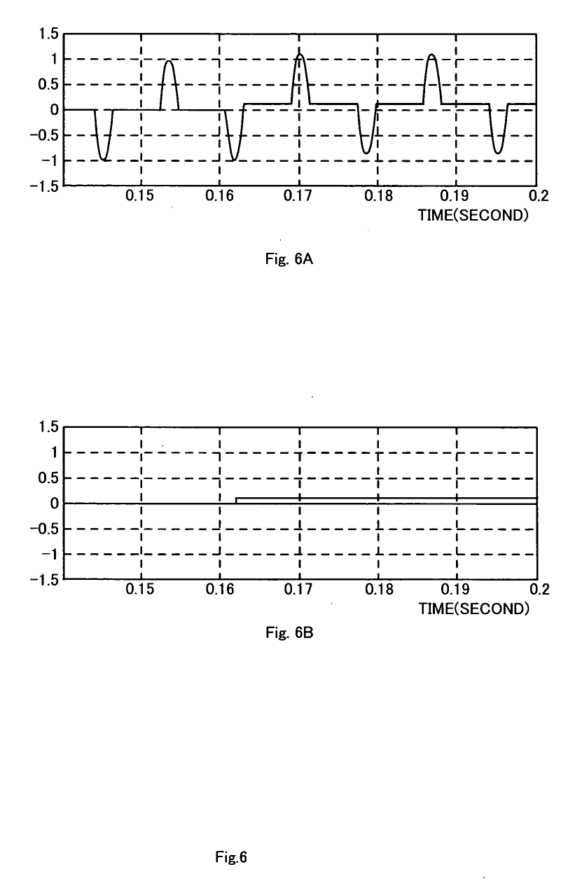

FIG. 5 is a diagram for explaining the validity of the embodiment of the present invention. In this drawing, an input signal 50 is a signal shown in FIG. 6A. The delay circuit 10 is a circuit having the configuration shown in FIG. 1. A subtracting circuit 51 outputs the result of the input signal 50 minus the output of the delay circuit 10. The output signal 52 is an output from the subtracting circuit 51.

In such a circuit as shown in FIG. 5, the case where an input signal as shown in FIG. 6A to which a disturbance as shown in FIG. 6B is overlaid is inputted will be discussed. Incidentally, a signal shown in FIG. 6B is a step signal which rises when t=0.162 [sec].

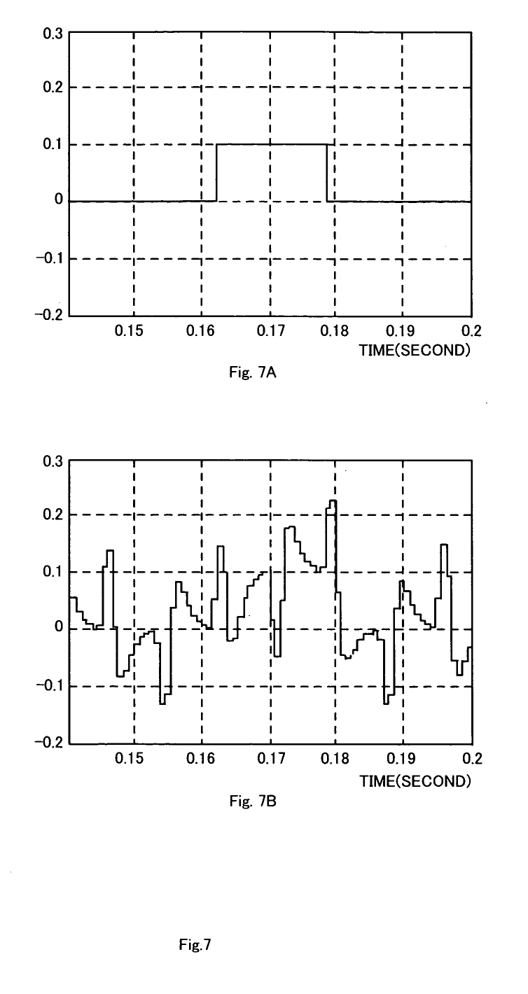

When such a signal is inputted and when the delay circuit 10 operates ideally, the signal as shown in FIG. 7A is outputted.

FIG. 7B is a diagram showing an output signal in the case where one datum in the vicinity of T₀ (a datum nearer to T₀) is used (when M=1). As shown in the drawing, when M=1, the waveform is substantially different from an ideal one shown in FIG. 7A. This is considered due to the difference between T₀/Tss=20.505 and floor [T₀/Tss]=20.

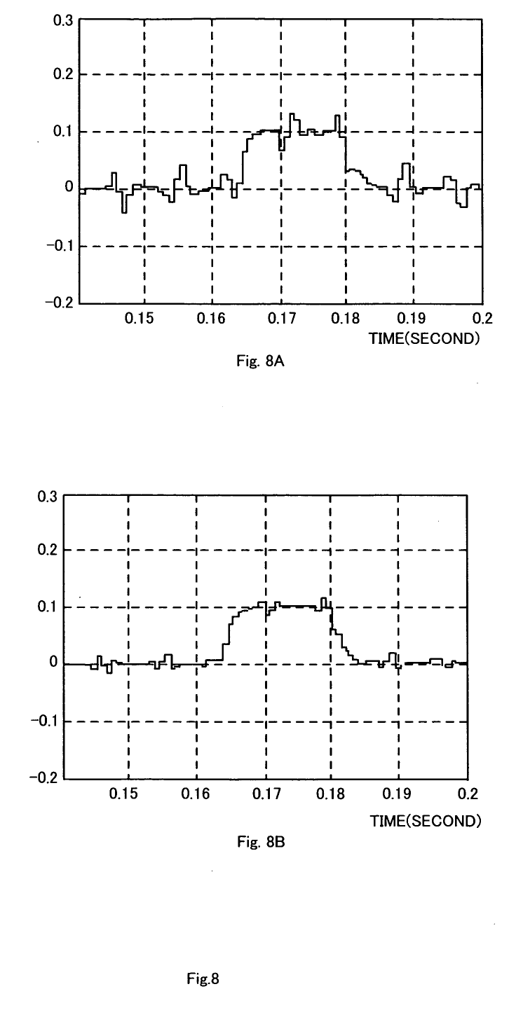

FIG. 8A is a diagram showing an output waveform when M=2 (in the case of linear interpolation). As shown in the drawing, if M=2, as compared with the case shown in FIG. 7B, the waveform is close to the ideal output waveform shown in FIG. 7A.

FIG. 8B is a diagram showing an output waveform when M=4 (in the case of cubic interpolation). As shown in the drawing, if M=4, as compared with the cases in FIG. 7B and FIG. 8A, the waveform is closer to the ideal output waveform shown in FIG. 7A.

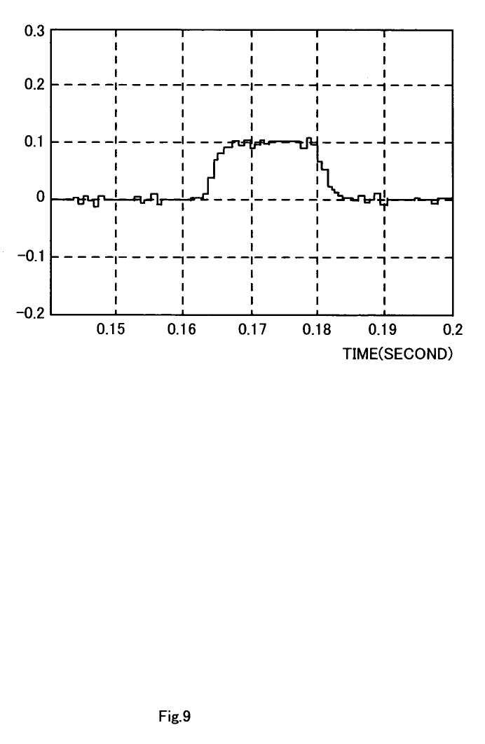

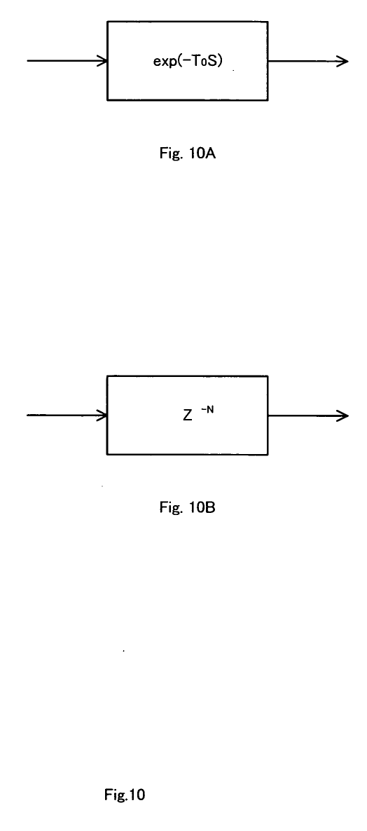

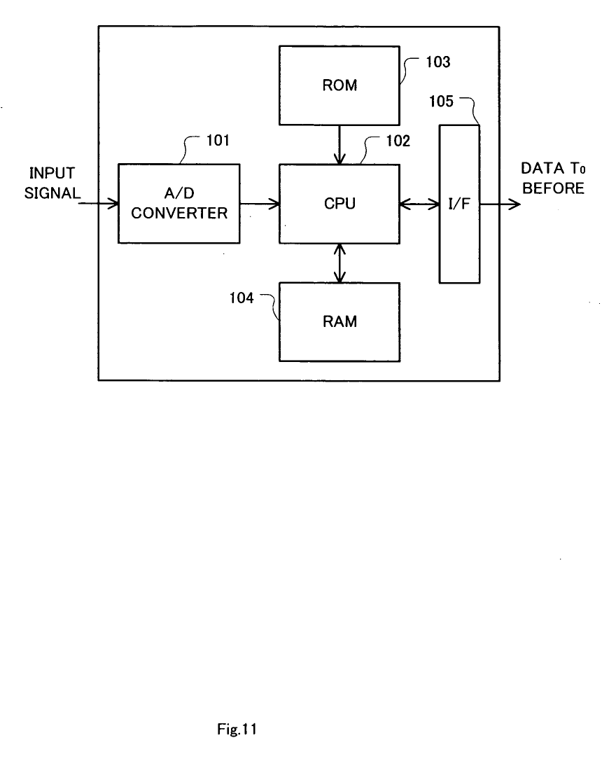

FIG. 9 is a diagram showing an output waveform when M=6 (in the case of quintic interpolation). As shown in the drawing, if M=6, as compared with the cases in FIG. 7B and FIG. 8A, the waveform is closer to the ideal output waveform shown in FIG. 7A, yet the waveform is much the same as in FIG. 8B.

As described in the above, according to the embodiment of the present invention, M=3 or below is acceptable, however, a condition of M=4 or more under which an output signal closer to the ideal waveform is obtainable is desirable. Besides, considering calculation volume, M=4 is further desirable.

As described hereinbefore, according to the embodiment of the present invention, the signal at the time that is T₀ before is estimated using M data in the vicinity of the signal with the (M−1) polynominal, so that correct data can be obtained even if the sampling time period Ts is longer.

Further, the sampling time period can be made longer which enables to reduce the storage area of the RAM 14, so that the production cost can be reduced.

Incidentally, in the above embodiment, as an arithmetical unit for the delay circuit 10, the DSP 12 is employed, whereas, a CPU can be employed. Also, as peripheral circuits of the DSP 12, the A/D converter 11, the ROM 13, the RAM 14, and the I/F 15 are provided, whereas, a part or all of these can be built in the DSP 12.

Further, the measurement of the time period of the input signal shown in FIG. 3 is designed to be performed for every time period, whereas, the same may be performed at intervals of two time periods or more.

Furthermore, in the above embodiment, the data delayed by the delay circuit 10 is designed to be inputted into the UPS control circuit 20, whereas, the other usage is also acceptable for the data.

Incidentally, the above function of processing can be realized by a computer. When using the computer, a program will be provided. In the program, the function of processing that the delay device should have is written. By executing the program on the computer, the above-mentioned function of processing is realized on the computer. The processing program can be recorded in a program product such as computer-readable recording media. As computer-readable recording media, there are a magnetic-recording device, an optical disk, a magneto-optic recording medium, a semiconductor memory, and the like. As magneto-optic recording devices, there are a hard disk drive (HDD), a flexible disk (FD), a magnetic tape, and the like. As optical disks, there are a DVD (Digital Versatile Disk), a DVD RAM (Random Access Memory), a CD-ROM (Compact Disk Read Only Memory), CD-R (Recordable)/RW (ReWritable), and the like. As magneto-optic recording media, there are an MO (Magneto-Optical disk), and the like.

For distributing the program, for instance, a portable recording media such as the DVD and the CD-ROM in which the program is recorded are offered. Alternatively, the program can be transferred via a network from a server computer storing the program to the other computer.

The computer for executing the program stores in its memory device the program, for example, that is recorded in the portable recording medium or that is transferred from the server computer. The computer reads out the program from its memory device to execute a processing in accordance with the program. Alternatively, the computer can execute the processing according to the program by directly reading out the program from the portable memory medium. Further, the computer can execute a processing, on a case-by-case basis, in accordance with the program it received.

The present invention may be used in a delay circuit which outputs a signal with periodicity by delaying the same.

The present invention enables to provide a delay device with high resolution, a power supply device using such a delay device, and a program product for delaying signals which can realize such a delay device.

1. A delay device which is inputted a signal with periodicity and outputs the signal after a delay by a prescribed time T₀, comprising:
a sampling circuit for sampling the signals with periodicity at intervals of a prescribed time period Tₛ;
a storage circuit for storing data sampled by said sampling circuit in a past certain amount of time; and
an estimation circuit for estimating a value of a signal at a time that is the prescribed time T₀ before a certain time point and between the samplings based on the data stored in said storage circuit.

2. The delay device according to claim 1,
wherein said estimation circuit estimates the value of the signal at the time that is the prescribed time T₀ before using M (M>1) data stored in said storage circuit and existing in the vicinity of the datum to be estimated by interpolating the data into an (M−1) polynominal.

3. The delay device according to claim 1,
wherein said estimation circuit estimates the value of the signal that is the prescribed time T₀ before using four data stored in said storage circuit and existing in the vicinity of the datum to be estimated by interpolating the data into a cubic polinominal.

4. The delay device according to claim 1 further comprising:
a measurement circuit for measuring a time period of the signal, and
a reset means for resetting a value of a parameter used by said estimation circuit for estimating the value of the signal in response to the measurement result of said measurement circuit.

5. The delay device according to claim 1,
wherein said sampling circuit samples at shorter intervals than the intervals for storing in said storage circuit, and
said delay device further comprising a filtering circuit for filtering the data sampled by said sampling circuit.

6. A power supply device having a delay device which is inputted a detection signal of voltage or current of a commercial power source and outputs the signal after a delay by a prescribed period of time T₀ being a time period of the voltage or electric current of the commercial power source or its integral multiple, comprising:
a sampling circuit for sampling the detection signals of the voltage or current of the commercial power source at intervals Ts which is shorter than the prescribed period of time T₀ being a time period of the voltage or current of commertial electric source or integral multiple of the time period,
a storage circuit for storing the data sampled by said sampling circuit in a past certain amount of time,
an estimation circuit for estimating a value of a detection signal at one point being the prescribed time T₀ before a certain time point and between the samplings based on the data stored in said storage circuit, and
a control circuit for controlling an internal circuit of said power supply device based on the value obtained by said estimation circuit.

7. A computer-readable program product for delaying signals, which makes a computer execute a processing of inputting a signal with periodicity and outputting the signal after a delay by a prescribed time T₀, makes the computer function as a sampling means for sampling the signals with periodicity at intervals of a prescribed time period Tₛ, a storage means for storing the data sampled by the sampling means in a past certain amount of time, an estimate means for estimating a value of the signal at a time that is the prescribed time T₀ before a certain time point and between the samplings based on the data stored in the storage means.
